(19) United States
(12) Patent Application Publication
(10) Pub. No.: US 2026/0223481 A1
(43) Pub. Date: Jul. 30, 2026

(54) METHODS FOR CONTROLLING PASSIVATING CONTACT THICKNESS IN BACKSIDE CONTACT SOLAR CELLS

(71) Applicant: Maxeon Solar Pte. Ltd., Singapore (SG)

(72) Inventors: Gerly Reich, San Jose, CA (US); David D. Smith, Campbell, CA (US)

(73) Assignee: Maxeon Solar Pte. Ltd., Singapore (SG)

(21) Appl. No.: 19/036,047

(22) Filed: Jan. 24, 2025

(51) Int. Cl. H10F 77/30; H10F 71/00

(52) U.S. Cl. CPC H10F 77/311; H10F 71/129

(57) ABSTRACT

A method of forming a solar cell is disclosed. The method includes forming a multilayered stack of materials that includes a substrate, forming a plurality of trenches in a polysilicon layer of the multilayered stack of materials to form a plurality of first polysilicon regions and one or more second polysilicon regions, after forming the plurality of trenches, forming a first doped material on exposed backside surfaces of the multilayered stack of materials, using the first doped material to cause the plurality of first polysilicon regions to have a doping type that corresponds to the doping type of the first doped material, using a second doped material to cause the one or more second polysilicon regions to have a doping type that corresponds to the doping type of the second doped material, and removing the first doped material.

### TECHNICAL FIELD

Embodiments of the disclosure pertain to backside contact solar cell contacts, and in particular, methods for controlling passivating contact thickness.

### BACKGROUND

Solar cells are devices for converting solar radiation to electrical energy. They may be fabricated on a semiconductor wafer using semiconductor processing technology. A solar cell includes p-type and n-type doped regions. Solar radiation impinging on the solar cell creates electrons and holes that migrate to the doped regions and create voltage differentials between them that generate electrical current. In a backside contact solar cell, both doped regions and metal contacts are located on the backside of the solar cell. The metal contacts allow external electric circuits to be coupled to and powered by the solar cell. Efficiency is an important characteristic of solar cells that is related to their capacity to generate power. However, there are significant challenges related to the design and fabrication of solar cells with improved efficiency.

### BRIEF DESCRIPTION OF THE DRAWINGS

FIG. 1A illustrates an exemplary operating environment of photovoltaic modules having solar cells whose passivating contacts have thicknesses that has been controlled according to one embodiment.

FIG. 1B shows a cross-section of a portion of a solar cell whose passivating contacts have thicknesses that have been controlled according to one embodiment.

FIG. 1C illustrates the positioning of a plurality of trenches around a plurality of polysilicon structures in the solar cell of FIG. 1B according to one embodiment.

FIG. 1D illustrates the positioning of a trench around a polysilicon structure in the solar cell of FIG. 1B according to one embodiment.

FIGS. 2A-2I are illustrations of cross-sections of a multilayered semiconductor structure during fabrication of a solar cell according to one embodiment.

### DESCRIPTION OF THE EMBODIMENTS

are described. It should be appreciated that although embodiments are described herein with reference to example methods for controlling passivating contact thickness in backside contact solar cells, the disclosure is more generally applicable to methods for controlling contact thickness in backside contact solar cells as well as other type methods for controlling passivating contact thickness in backside contact solar cells. In the following description, numerous specific details are set forth, in order to provide a thorough understanding of embodiments of the present disclosure. It will be apparent to one skilled in the art that embodiments of the present disclosure may be practiced without these specific details. In other instances, well-known features, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As used herein the term “doping” is intended to refer to the introduction of impurity elements into material to give the material desired properties.

In one embodiment, as used herein “doping” can be performed by methods that can include but are not limited to diffusion and ion implantation.

In one embodiment, as used herein the term “backside” is intended to refer to a backside of a solar cell that is opposite to the front side of the solar cell, wherein the front side of the solar cell faces the sun during normal operation. In one embodiment, as used herein the term “backside contact solar cell” is intended to refer to a solar cell where all electrical connections to its collection regions are formed on its backside. In one embodiment, in a backside contact solar cell, both doped regions and interdigitated metal contact fingers coupled to them, are located on the backside of the solar cell. In one embodiment, the contact fingers allow an external electrical circuit to be coupled to and powered by the solar cell.

In one embodiment, the term “non-contiguous” polysilicon is intended to refer to non-continuous and separated portions of polysilicon. In particular, to a plurality of non-continuous and separated (by surrounding trenches) polysilicon islands having a bounded periphery that can include various shapes.

In one embodiment, as used herein the term “dotted” is intended to refer to a structural organization of polysilicon in a solar cell that is characterized by the presence of an ordered plurality of non-contiguous and electrically separated polysilicon islands that are surrounded by trenches.

As used herein the term “multilayered stack of materials” or “semiconductor structure”, when used in the context of a description of a process or method step or operation, is intended to refer to the “multilayered stack of materials” or “semiconductor structure” as it existed at the time that the process or method step or operation is executed.

Solar cells convert solar radiation to electrical energy. A solar cell typically includes p-type and n-type doped regions. Solar radiation impinging the surface of the solar cell creates electrons and holes that migrate to the doped regions and cause voltage differentials to develop between the doped regions. In a backside contact solar cell, the doped regions and metal contacts that are coupled to them are located on the backside of the solar cell. The metal contacts allow an external electrical circuit to be coupled to and powered by the solar cell.

Passivating contacts are charge carrier selective contacts that are used in silicon based solar cells. Two types of passivating contacts are n and p type polycrystalline silicon on SiOx passivating contacts. n and p type polycrystalline silicon on SiOₓ passivating contacts are respectively, electron, and hole, selective, high-efficiency contacts. Contacting the polysilicon contacts can be challenging because the energy needed to form contacts through thick oxides can cause damage beyond the polysilicon contact. Moreover, because of such damage, a thicker polysilicon layer can be required to provide a buffer that enables the contact to absorb such damage an retain sufficient robustness to provide an effective contact.

Solar cell efficiency is an important operational characteristic of solar cells as solar cell efficiency is directly related to a solar cell's capacity to generate power. Free carrier absorption is a significant factor in the determination of solar cell efficiency because photons that are absorbed by free carriers may not provide a net contribution to the current that is produced by a solar cell. Thick polysilicon contacts exhibit less favorable free carrier absorption properties as compared to thin polysilicon contacts. This is because thin polysilicon contacts experience less optical losses from free carrier absorption of infrared light than do thicker polysilicon contacts.

A method of forming a solar cell is disclosed herein that addresses the aforementioned challenges of manufacturing conventional solar cells. The method includes forming a multilayered stack of materials that includes a substrate, forming a plurality of trenches in a polysilicon layer of the multilayered stack of materials to form a plurality of first polysilicon regions and one or more second polysilicon regions, after forming the plurality of trenches, forming a first doped material on exposed backside surfaces of the multilayered stack of materials, using the first doped material to cause the plurality of first polysilicon regions to have a doping type that corresponds to the doping type of the first doped material, using a second doped material to cause the one or more second polysilicon regions to have a doping type that corresponds to the doping type of the second doped material, and removing the first doped material. The method further includes after removing the first doped material, forming a layer of aluminum oxide (AlOx) on exposed frontside surfaces of the multilayered stack of materials and on the exposed backside surfaces of the multilayered stack of materials, and forming a layer of silicon nitride on the layer of aluminum oxide.

In one embodiment, using the processes that are described herein, to limit the thickness of passivating polysilicon contacts (to provide thin passivating polysilicon contacts) of a solar cell, can have a favorable effect on the free carrier absorption properties of the solar cell. In particular, the solar cell architecture resulting from such processes, that features the desired thin polysilicon passivating contacts, structurally limits the opportunities for free carrier absorption of photons that may be available in conventionally designed solar cells. In one embodiment, the limiting of opportunities for free carrier absorption of light is designed to reduce the wasting of light energy due to free carrier absorption, where photons are absorbed by electrons or holes and do not generate new electron-hole pairs. Reducing such waste increases solar cell efficiency.

### Solar Cell

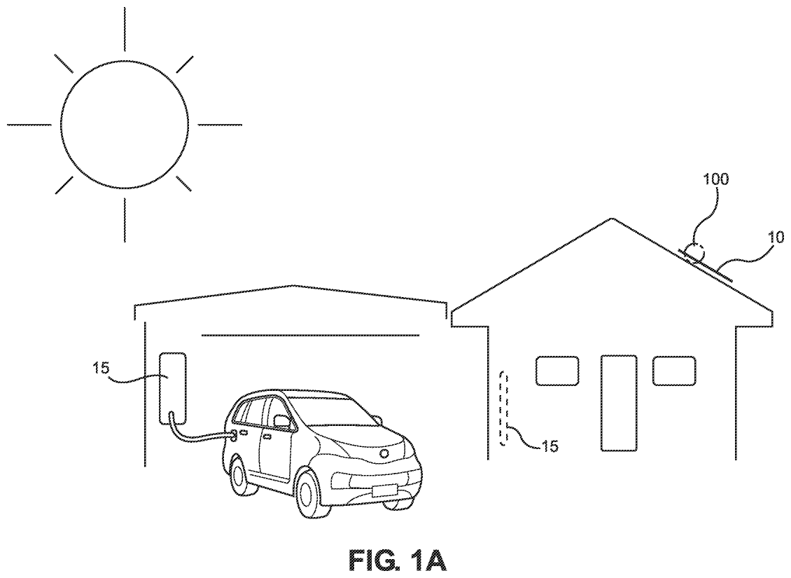

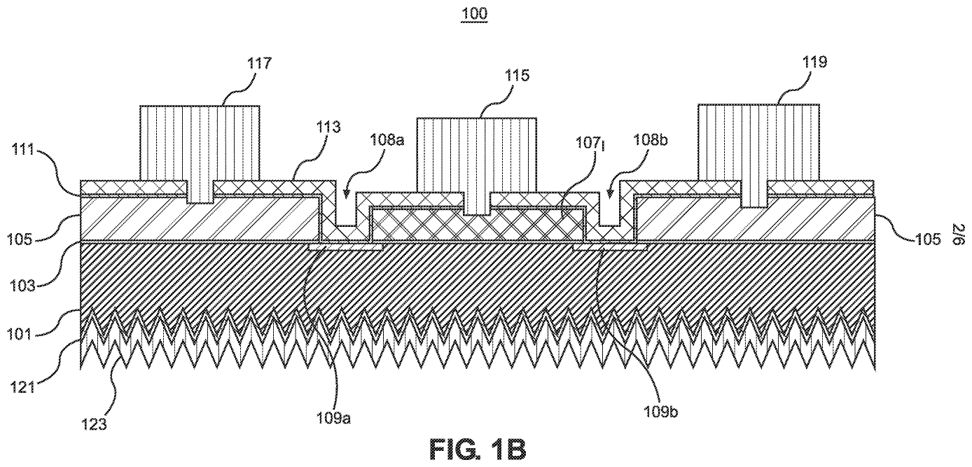

FIG. 1A illustrates an exemplary operating environment of photovoltaic modules having solar cells whose passivating contacts have a controlled coverage area fraction according to one embodiment. FIG. 1A shows a house that has photovoltaic modules 10 that include solar cells 100 (hereinafter “the solar cells” or “a solar cell” or “the solar cell”) that are installed on its roof. In one embodiment, the photovoltaic modules 10 utilize the electrical energy generated by the solar cells 100 to supply the house with electricity (e.g., to power appliances 15). It should be noted that the depicted residential operating environment is only exemplary and that embodiments are equally useful in many other types of operating environments such as commercial.

FIG. 1B shows a cross-section of a portion of the solar cell 100 according to one embodiment. In one embodiment, the solar cell 100 includes wafer 101, tunnel oxide 103, n-doped polysilicon region 105a, n-doped polysilicon region 105b, p-doped polysilicon layer 107₁, trench 108a, trench 108b, doped region 109a, doped region 109b, dielectric layer 111, dielectric layer 113, conductor layer 115, conductor layer 117, conductor layer 119, dielectric layer 121, and dielectric layer 123.

Referring to FIG. 1B, the wafer 101 forms the substrate upon which the semiconductor, dielectric and conductor layers of the solar cell 100 are formed. In one embodiment, the tunnel oxide 103 is formed on the surface of the wafer 101 and includes spaces through which the doped regions 109a and 109b are formed, and in which the dielectric layer 111 is formed. In one embodiment, the p-doped polysilicon layer 107₁ is formed on a portion of the wafer 101 between laterally situated n-doped polysilicon region 105a and n-doped polysilicon region 105b. In one embodiment, the p-doped polysilicon layer 107₁ includes sides that are covered by the dielectric layer 111 and a top surface that is partially covered by the dielectric layer 111. In addition, in one embodiment, the p-doped polysilicon layer 107₁ is contacted on its top surface through a space in the dielectric layer 111 by conductor layer 115. In one embodiment, the n-doped polysilicon regions 105a and 105b are formed on the surface of the tunnel oxide 103 and are separated from the p-doped polysilicon layer 107₁ by portions of the dielectric layer 111 that extend into the space that surrounds the p-doped polysilicon layer 107₁. In one embodiment, the doped region 109a is formed in the wafer 101 below a portion of the dielectric layer 111 that extends into a first space in the tunnel oxide 103. In addition, in one embodiment, the doped region 109a laterally extends underneath a portion of the tunnel oxide 103 that is formed underneath the p-doped polysilicon layer 107₁ and a portion of the tunnel oxide 103 that is formed underneath the n-doped polysilicon region 105a. In one embodiment, the doped region 109b is formed in the wafer 101 below a portion of the dielectric layer 111 that extends into a second space in the tunnel oxide 103. In addition, in one embodiment, the doped region 109b laterally extends underneath a portion of the tunnel oxide 103 that is formed underneath the p-doped polysilicon layer 107₁ and a portion of the tunnel oxide 103 that is formed underneath the n-doped polysilicon region 105b. In one embodiment, the dielectric layer 111 extends along the top and inner side surface of the n-doped polysilicon region 105a, on the surface of the wafer 101 between the n-doped polysilicon region 105a and the p-doped polysilicon layer 107₁, along the top and side surfaces of the p-doped polysilicon layer 107₁, on the surface of the wafer 101 between the p-doped polysilicon layer 107₁ and the n-doped polysilicon region 105b, and along the top and inner side surface of the n-doped polysilicon region 105b. In one embodiment, the dielectric layer 113 covers and extends along the entire the top surface of the dielectric layer 111. In one embodiment, the dielectric layer 111 and the dielectric layer 113 include openings above the p-doped polysilicon layer 107₁, the n-doped polysilicon region 105a, and the n-doped polysilicon region 105b that enable the p-doped polysilicon layer 107₁, the n-doped polysilicon region 105a and the n-doped polysilicon region 105b to be contacted by the conductor layer 115, the conductor layer 117 and the conductor layer 119 respectively. In one embodiment, the dielectric layer 121 is formed on the textured frontside surface of solar cell 100. In one embodiment, the dielectric layer 123 is formed on the dielectric layer 121 on the frontside of solar cell 100.

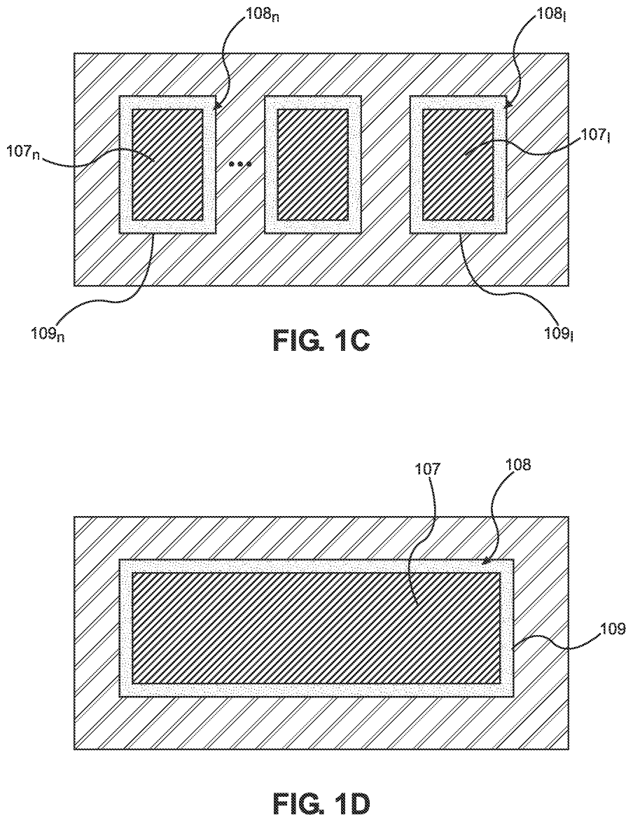

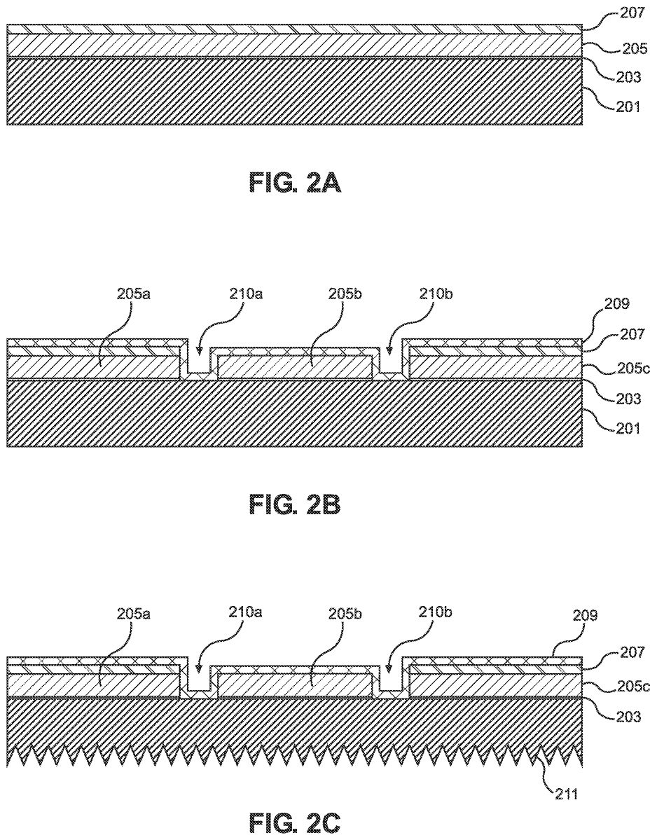

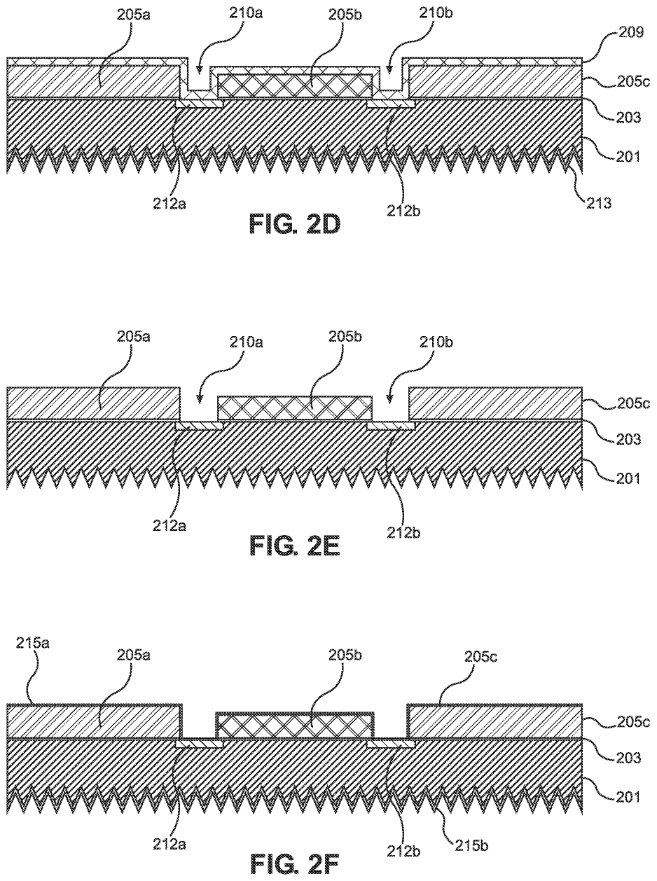

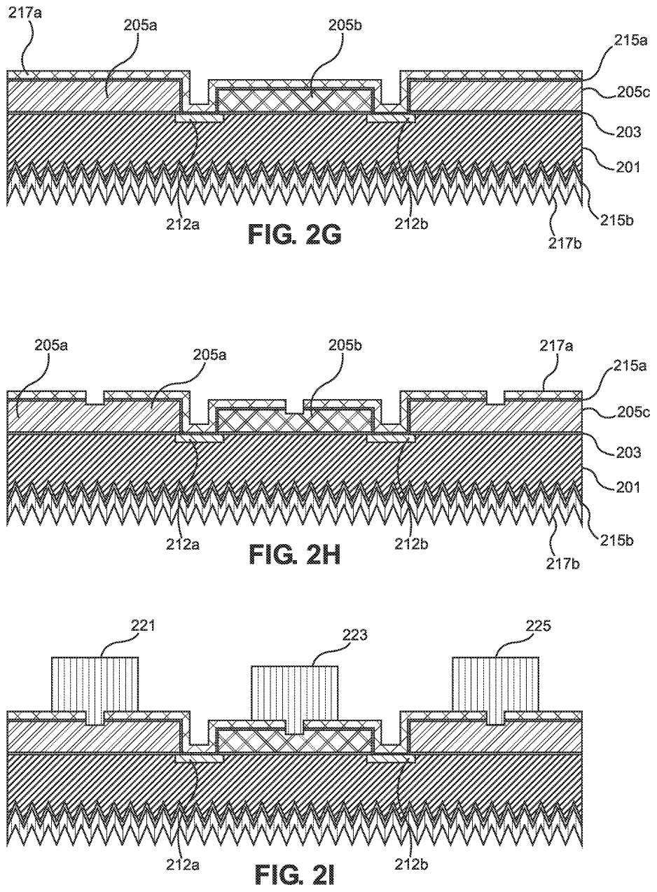

Referring to FIG. 1C, in one embodiment, the trenches 108a and 108b, shown in FIG. 1B, are opposite side cross-sectional parts of a trench 108₁ that is formed around the p-doped polysilicon layer 107₁ (a cross-sectional representation of a first polysilicon island of a plurality of polysilicon islands). Moreover, in one embodiment, the trench 108₁ is one of a plurality of trenches 108₁-108ₙ formed around the plurality of polysilicon islands 107₁-107ₙ (that constitute non-contiguous or “dotted” passivating contact regions) in solar cell 100 (see FIG. 1C). In one embodiment, the trenches can have shapes that can include but are not limited to circular, rectangular, elongated, elliptical, polygonal and irregular. In one embodiment, the polysilicon islands 107₁-107ₙ have a thickness of 110 nm. In other embodiments, the polysilicon islands 107₁-107ₙ have other thicknesses. In one embodiment, the trenches 108₁-108ₙ are formed using a self-aligned process that is described herein with reference to FIGS. 2A-2K and 3A-3I. In one embodiment, self-alignment enables the formation of a narrower trench than can be obtained by some other conventional processes.

FIG. 1D shows an embodiment that includes a single elongated polysilicon island 107 that is surrounded by a trench 108 (also shown is doped region 109 and n-doped polysilicon region 105). In other embodiments a combination of the respective embodiments shown in FIG. 1C and FIG. 1D can be used.

In one embodiment, the polysilicon islands 107₁-107ₙ are a plurality of non-contiguous doped polysilicon regions of p-type conductivity that are formed in lasered regions of the semiconductor structure (see FIGS. 2A-2I).

In one embodiment, the wafer 101 can be formed from silicon. In other embodiments, the wafer 101 can be formed from other materials. In one embodiment, the tunnel oxide 103 can be formed from silicon oxide. In other embodiments, the tunnel oxide 103 can be formed from other materials. In one embodiment, the n-doped polysilicon regions 105a and 105b can be doped with phosphorous. In other embodiments, the n-doped polysilicon regions 105a and 105b can be doped with other impurities. In one embodiment, the p-doped polysilicon layer 107₁ can be doped with boron. In other embodiments, the p-doped polysilicon layer 107₁ can be doped with other impurities. In one embodiment, the doped regions 109a and 109b can be doped with boron. In other embodiments, the doped regions 109a and 109b can be doped with other materials. In one embodiment, the dielectric layer 111 can include aluminum oxide. In other embodiments, dielectric layer 111 can include other materials. In one embodiment, the dielectric layer 113 can include silicon nitride. In other embodiments, the dielectric layer 113 can include other materials. In one embodiment, the conductor layer 115 can include aluminum, nickel, chromium, gold, germanium, copper, silver, titanium, tungsten, tin, platinum, and tantalum. In other embodiments, the conductor layer 115 can include other materials. In one embodiment, the conductor layer 117 can include aluminum, nickel, chromium, gold, germanium, copper, silver, titanium, tungsten, tin, platinum, and tantalum. In other embodiments, the conductor layer 117 can include other materials. In one embodiment, the conductor layer 119 can include aluminum, nickel, chromium, gold, germanium, copper, silver, titanium, tungsten, tin, platinum, and tantalum. In other embodiments, the conductor layer 119 can include other materials. In one embodiment, the dielectric layer 121 can be formed from aluminum oxide. In other embodiments, the dielectric layer 121 can be formed from other materials. In one embodiment, dielectric layer 123 can be formed from silicon nitride In other embodiments, the dielectric layer 123 can be formed from other materials.

### Operation

In operation, upon exposure to light, the solar cell 100 converts light energy into electricity based on the photovoltaic effect. Some carriers reach the p-n junction and contribute to the current produced by the solar cell 100 and others do not. Free carrier absorption is a significant factor in the determination of solar cell efficiency because photons that are absorbed by carriers will not provide a net contribution to the current that is produced by a solar cell. However, the thin polysilicon passivated contacts of solar cell 100 are designed to incur less optical losses from free carrier absorption of infrared light than does thicker polysilicon. As such, the architecture of solar cell 100 structurally limits the opportunities for free carrier absorption of photons in contrast to solar cells that feature thicker polysilicon passivated contacts. In one embodiment, the limiting of opportunities for free carrier absorption is designed to reduce the wasting of light energy due to free carrier absorption, where photons are absorbed by electrons or holes and do not generate new electron-hole pairs. Reducing such waste of light energy increases solar cell efficiency. A high Jsc is provided as more light is being absorbed and converted into electricity, thus contributing significantly to the overall power output of the solar cell 100.

### Solar Cell Fabrication Process

FIGS. 2A-2I are illustrations of cross-sections of semiconductor structure 200 that includes a multilayered stack of materials during fabrication of a solar cell according to one embodiment. FIG. 2A shows a cross-section of the semiconductor structure 200 after initial operations that involve the preparation of a multilayered stack of semiconductors and a dielectric. In one embodiment, the semiconductor structure 200 includes wafer 201, tunnel oxide 203, intrinsic polysilicon region 205, and amorphous silicon layer (a-Si) 207.

Referring to FIG. 2B, after the operations that result in the cross-section shown in FIG. 2A, the intrinsic polysilicon layer 205 of the multilayered semiconductor structure is separated into intrinsic polysilicon region 205a, intrinsic polysilicon region 205b, and intrinsic polysilicon region 205c. In addition, the intrinsic polysilicon region 205b is formed into a plurality of islands that are surrounded by trenches 210a and 210b. As shown in FIG. 2B, operations associated with FIG. 2B, leave portions of n-type a-Si layer 207 on the top surfaces of the intrinsic polysilicon region 205a and the intrinsic polysilicon region 205c. And, as shown in FIG. 2B, the operations result in the formation of a BSG layer 209 on the top surface of the n-type a-Si layer 207 (that is formed on the top surfaces of the intrinsic polysilicon region 205a and the intrinsic polysilicon region 205c), on the top surface of the intrinsic polysilicon region 205b, and on the surfaces that form the trenches 210a and 210b that surround the polysilicon islands 205b (it should be appreciated that side surfaces of the intrinsic polysilicon regions 205a, 205b and 205c form parts of the sidewalls of the trenches 210a and 210b).

Referring to FIG. 2C, after operations that result in the cross-section shown in FIG. 2B, texturing and cleaning operations are performed. As part of the texturing and cleaning operations, an 80 degree Celsius, 6 percent potassium hydroxide (KOH) texturing operation followed by a Hydrofluoric Acid/Ozone (HF/O3) bath is performed to clean the semiconductor structure 200 (to prepare the semiconductor structure for PDrive operations; see FIG. 2D). In other embodiments, other texturing and cleaning operations can be performed. In one embodiment, the texturing operations cause a texturing of the front surface of the semiconductor structure 200. In one embodiment, the BSG layer 209 is used in subsequent operations as the dopant source from which p-type dopants are diffused into the polysilicon region 205b.

Referring to FIG. 2D, after operations that result in the cross-section shown in FIG. 2C, a high temperature dopant drive operation (PDrive operation) is performed. As part of the high temperature dopant drive operation, a high temperature anneal is performed using O₂ to oxidize the front surface of the semiconductor structure 200 and form thin oxide layer 213. In one embodiment, the high temperature anneal causes a diffusion of boron from BSG layer 209 into the intrinsic polysilicon region 205b and into the wafer 201 (see doped regions 212a and 212b). In addition, the high temperature anneal causes a diffusion of n-type dopants from n-type a-Si layer 207 into n-type polysilicon regions 205a and 205c. In one embodiment, the diffusion of boron into the polysilicon region 205b creates a plurality of p-doped polysilicon islands (See FIG. 1C). In one embodiment, the doped region 212a is formed in the wafer 201 below a portion of the BSG layer 209 that extends into a first space in the tunnel oxide 203. In addition, in one embodiment, the doped region 212a laterally extends underneath a portion of the tunnel oxide 203 that is formed underneath the p-doped polysilicon layer 205b and a portion of the tunnel oxide 203 that is formed underneath the n-doped polysilicon region 205a. In one embodiment, the doped region 212b is formed in the wafer 201 below a portion of the BSG layer 209 that extends into a second space in the tunnel oxide 203. In addition, in one embodiment, the doped region 212b laterally extends underneath a portion of the tunnel oxide 203 that is formed underneath the p-doped polysilicon layer 205b and a portion of the tunnel oxide 203 that is formed underneath the n-doped polysilicon region 205c. In one embodiment, performing the high temperature dopant drive operation in a single thermal step reduces oxygen precipitates in silicon. In other embodiments, the dopant drive operation can be performed in other suitable manners.

Referring to FIG. 2E, after operations that result in the cross-section shown in FIG. 2D, an hydrofluoric acid/ozone (HF/O3) etch is performed to remove the BSG layer 209 and the thin oxide layer 213 on the textured front surface. In one embodiment, the removal of the BSG layer 209 exposes bare silicon surfaces of the semiconductor structure 200.

Referring to FIG. 2F, after operations resulting in the cross-section shown in FIG. 2E, AlOx layers 215a and 215b are formed on respective sides of the semiconductor structure 200. In one embodiment, the AlOx layers 215a and 215b are formed using atomic layer deposition (ALD). In other embodiments, the AlOx layers 215a and 215b can be formed by other suitable methods. In one embodiment, after the AlOx layers 215a and 215b are formed, an anneal is performed to passivate non-polysilicon coated surfaces.

Referring to FIG. 2G, after operations resulting in the cross-section shown in FIG. 2F, silicon nitride (SiNx) layers 217a and 217b are formed on the AlOx layers 215a and 215b on respective sides of the semiconductor structure 200. In one embodiment, the SiNx layer can be formed using PECVD. In other embodiments the SiNx layer can be formed using other methods.

Referring to FIG. 2H, after one or more operations resulting in the cross-section shown in FIG. 2G, openings are formed through the AlOx layer 215a and the SiNx layer 217a. In addition, in one embodiment, a space is formed in the top surfaces of polysilicon region 205a, polysilicon region 205b and polysilicon region 205c. In one embodiment, the openings formed through the AlOx layer 215a and the SiNx layer 217a, and the space formed in the top surface of polysilicon region 205a, polysilicon region 205b and polysilicon region 205c, are formed using a laser. In one embodiment, the openings formed through the AlOx layer 215a and the SiNx layer 217a, and the space formed in the top surfaces of polysilicon region 205a, polysilicon region 205b and polysilicon region 205c are formed to accommodate conductive contacts. In one embodiment, forming the openings without having to laser through boron, enables a larger contact opening, and causes less damage to the polysilicon regions. This enables the use of a thin polysilicon region 205b which results in less optical losses from free carrier absorption and a high Jsc.

Referring to FIG. 2I, after one or more operations resulting in the cross-section shown in FIG. 2H, conductor layer 221, conductor layer 223, and conductor layer 225 are formed in the openings in AlOx layer 215a and the SiNx layer 217a to contact, respectively, polysilicon region 205a, polysilicon region 205b and polysilicon region 205c.

It should be appreciated that contacts can be difficult to open through a BSG film on the semiconductor structure. Forming contacts through BSG film results in a tight process space for forming the contacts and can yield contacts that can have variable and poor contact resistance. This is especially risked when combined with aluminum wire metallization. Additionally, polysilicon layers must be thick (e.g., 200 nm), in order to provide a buffer from the damage caused by the high levels of power that it takes to laser through the BSG layer. As described herein, thick polysilicon layers results in absorption of free carriers and loss of efficiency.

In one embodiment, when a contact is formed through a silicon nitride layer and an AlOx layer, the silicon nitride layer and the AlOx layer can be thin, and the nitride layer can be more absorbing of laser light, making ablation and contact formation easier. It should be appreciated that BSG is transparent to laser light. Thus, some of the polysilicon layer must be melted to form the contact opening when BSG is used. Because of this, avoiding the use of a BSG layer can have a positive effect on contact formation, allowing thinner polysilicon layers.

Disclosed process embodiments enable improved interdigitated back contact (IBC) cell efficiency and low-cost manufacturing. As part of the processes, as described with reference to FIGS. 2A-2I, BSG is formed as a part of a self-aligned polysilicon dot structure, where the BSG serves as a boron source and cap oxide of the wafer back side, texturization of the wafer front side is performed, a high temperature drive for boron diffusion is performed, a complete etch of the BSG is performed, AlOx is used to passivate both sides of the wafer, an anneal is performed to aid/improve AlOx passivation, nitride is formed on both sides of the wafer, and lasered contact openings and metallization are provided.

In one embodiment, a single thermal step process is provided that enables AlOx passivation, allows heavily doped BSG on the trench, protects texturing, enables tube nitride and BSG for low cost, reduces contact damage, and provides smoother surface contact openings. It also enables a thin polysilicon process that enables high short circuit current density (Jsc) (see description hereinabove).

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The various features of different embodiments may be variously combined with some features included and others excluded to suit a variety of different applications.

What is claimed is:

1. A method of forming a solar cell, comprising:
forming a multilayered stack of materials that includes a substrate;
forming a plurality of trenches in a polysilicon layer of the multilayered stack of materials to form a plurality of first polysilicon regions and one or more second polysilicon regions;
after forming the plurality of trenches, forming a first doped material on exposed backside surfaces of the multilayered stack of materials;
using the first doped material to cause the plurality of first polysilicon regions to have a doping type that corresponds to the doping type of the first doped material;
using a second doped material to cause the one or more second polysilicon regions to have a doping type that corresponds to the doping type of the second doped material;
removing the first doped material;
after removing the first doped material, forming a layer of aluminum oxide on exposed frontside surfaces of the multilayered stack of materials and on the exposed backside surfaces of the multilayered stack of materials; and
forming a layer of silicon nitride on the layer of aluminum oxide.

2. The method of forming a solar cell of claim 1, further comprising: after forming the aluminum oxide on the exposed frontside surfaces and on the exposed backside surfaces of the multilayered stack of materials, performing an anneal.

3. The method of forming a solar cell of claim 2, further comprising: after performing the anneal, forming a layer of silicon nitride on the surface of the aluminum oxide on both sides of the multilayered stack of materials.

4. The method of forming a solar cell of claim 3, further comprising: forming contact openings through the layer of aluminum oxide and the layer of silicon nitride.

5. The method of forming a solar cell of claim 1, further comprising: using a laser, forming contact opening in a top surface of the plurality of first polysilicon regions and the one or more second polysilicon regions.

6. The method of forming a solar cell of claim 1, further comprising:
after forming the first doped material on the exposed backside surfaces of the multilayered stack of materials, performing potassium hydroxide texturing followed by hydrofluoric acid and Oxone cleaning of the multilayered stack of materials.

7. A backside contact solar cell, comprising:
a substrate;
a first dielectric layer on a backside of the substrate;
a plurality of non-contiguous first passivating contact regions having a first polarity on the first dielectric layer;
at least one second passivating contact region having a second polarity on the first dielectric layer, laterally disposed to the plurality of non-contiguous first passivating contact regions;
a plurality of trenches separating the plurality of non-contiguous first passivating contact regions and the at least one second passivating contact region;
a second dielectric layer formed on a top and side surfaces of the plurality of non-contiguous first passivating contact regions, the top and inner side surfaces of the at least one second passivating contact region, and bottom surfaces of said plurality of trenches; and
a third dielectric layer formed on a top surface of the second dielectric layer.

8. The backside contact solar cell of claim 7, further comprising: lasered contact openings that extend through the second dielectric layer and the third dielectric layer and expose top surfaces of the plurality of non-contiguous first passivating contact regions.

9. The backside contact solar cell of claim 7, wherein the plurality of non-contiguous first passivating contact regions include p-doped semiconductor regions.

10. The backside contact solar cell of claim 7, wherein the at least one second passivating contact region includes n-doped semiconductor regions.

11. The backside contact solar cell of claim 8, further comprising one or more aluminum layers occupying the lasered contact openings and contacting the surfaces of the plurality of non-contiguous first passivating contact regions.
